(19) United States
(12) Patent Application Publication
(10) Pub. No.: US 2015/0243716 A1
(43) Pub. Date: Aug. 27, 2015

(54) ORGANIC LIGHT EMITTING DISPLAY AND METHOD OF MANUFACTURING THE SAME

(71) Applicant: SAMSUNG DISPLAY CO., LTD., Yongin-City (KR)

(72) Inventors: Min-Sung Kwon, Yongin-City (KR); Ki-Wan Ahn, Yongin-City (KR)

(21) Appl. No.: 14/567,982

(22) Filed: Dec. 11, 2014

(30) Foreign Application Priority Data
Feb. 26, 2014 (KR) 10-2014-0022513

(51) Int. Cl. H01L 27/32; H01L 51/52; H01L 51/56

(52) U.S. Cl. CPC H01L 27/3248; H01L 51/56; H01L 51/5228; H01L 51/5215; H01L 51/5221; H01L 2227/323

(57) ABSTRACT

An organic light emitting display includes a substrate, a first electrode, an organic emission layer, a second electrode, an insulating layer, and an auxiliary electrode. The substrate has at least one thin film transistor formed thereon. The first electrode is electrically coupled (e.g., electrically connected) to the thin film transistor on the substrate. The organic emission layer is formed on the first electrode. The second electrode is formed on the organic emission layer. The insulating layer is formed on the second electrode. The auxiliary electrode is formed on the insulating layer to be electrically coupled to the second electrode.

### CROSS-REFERENCE TO RELATED APPLICATION

This application claims priority to and the benefit of Korean Patent Application No. 10-2014-0022513, filed on Feb. 26, 2014, in the Korean Intellectual Property Office, the content of which is incorporated herein by reference in its entirety.

### BACKGROUND

1. Field

Aspects of embodiments of the present invention relate to an organic light emitting display and a method of manufacturing the same.

2. Description of the Related Art

An organic light emitting display is a flat panel display using (utilizing) organic light emitting diodes, and has desired features of wide use (usage) temperature range, strong resistance against impact or vibration, wide viewing angles, and clean motion picture due to fast response speed, as compared with other flat panel displays. Accordingly, the organic light emitting display has come into the spotlight as a next-generation flat panel display.

The amount of emission of an organic light emitting diode is controlled by a thin film transistor. The organic light emitting diode includes an anode electrode electrically coupled to the thin film transistor on a substrate with the thin film transistor formed thereon, an organic light emitting layer, and a cathode electrode formed on a front surface of the substrate including the organic light emitting layer.

When an organic light emitting diode is formed on a substrate, particles may be attached to the organic light emitting diode. For example, when particles (generated during a process of forming an anode electrode on the substrate) are attached to a surface of the anode electrode, an organic light emitting layer and a cathode electrode are formed on the anode electrode while surrounding the particles in a subsequent process.

The particles allow (may cause) the anode and cathode electrodes to be short-circuited by penetrating (connecting) between the anode and cathode electrodes, and therefore, potential dark spots may be caused (formed). Hence, a repair process for removing the particles is performed.

In the repair process, heat is generated by applying a reverse voltage to the anode electrode and the cathode electrode to which the particles are attached, and an oxide film is then formed on the surface of the cathode electrode surrounding the particles by exposing the anode and cathode electrodes under an oxygen atmosphere, so that the particles are insulated from a portion (of the cathode electrode) to which the particles are not attached.

### SUMMARY

Aspects of embodiments of the present invention are directed toward an organic light emitting display and a method of manufacturing the same, which can improve image quality by minimizing or reducing the occurrence of dark spot defects.

According to an embodiment of the present invention, an organic light emitting display includes: a substrate with at least one thin film transistor thereon; a first electrode electrically coupled to the thin film transistor on the substrate; an organic emission layer on the first electrode; a second electrode on the organic emission layer; an insulating layer on the second electrode; and an auxiliary electrode on the insulating layer and electrically coupled to the second electrode.

The first electrode may be a transparent electrode and the second electrode may be a reflective electrode.

The second electrode and the auxiliary electrode may include a same conductive material.

The insulating layer may include at least one opening through which a portion of the second electrode is exposed to an outside in other areas except an area in which the organic emission layer is formed.

The insulating layer and the auxiliary electrode may be on a front surface of the substrate.

The insulating layer and the auxiliary electrode may be in only areas except the area in which the organic emission layer is formed on the substrate.

A thickness of the second electrode may be 70 to 200 Å, and a thickness of the auxiliary electrode may be 1500 to 3000 Å.

According to another embodiment of the present invention, an organic light emitting display includes: a substrate with at least one thin film transistor thereon; a first electrode electrically coupled to the thin film transistor on the substrate; an organic emission layer on the first electrode; a second electrode on the organic emission layer; and an auxiliary electrode on the second electrode and electrically coupled to the second electrode.

The first electrode may be a transparent electrode and the second electrode may be a reflective electrode.

The second electrode and the auxiliary electrode may include a same conductive material.

The auxiliary electrode may only be in other areas except an area in which the organic emission layer is formed on the substrate.

According to an embodiment of the present invention, a method of manufacturing an organic light emitting display includes: forming at least one thin film transistor on a substrate; forming a first electrode electrically coupled to the thin film transistor on the substrate; forming an organic emission layer on the first electrode; forming a second electrode on the organic emission layer; forming an insulating layer on the second electrode, the insulating layer patterned to include at least one opening through which a portion of the second electrode is exposed to an outside; and forming an auxiliary electrode electrically coupled to the second electrode through the opening on the insulating layer.

The forming of the insulating layer and the forming of the auxiliary electrode may include forming an insulating material layer on a front surface of the substrate with the second electrode formed thereon; forming the insulating layer including the at least one opening through which a portion of the second electrode is exposed to the outside by patterning a portion of the insulating material layer not overlapped with the organic emission layer; and forming an auxiliary electrode on a front surface of the insulating layer to be electrically coupled to the second electrode through the at least one opening.

The forming of the insulating layer and the forming of the auxiliary electrode may include forming an insulating material layer on a front surface of the substrate with the second electrode formed thereon; forming the insulating layer including at least one opening through which a portion of the second electrode is exposed to the outside by patterning a portion of the insulating material layer not overlapped with the organic emission layer, and further forming a second opening through which a portion of the second electrode is exposed to the outside by patterning a portion of the insulating material layer overlapped with the organic emission layer; disposing a mask on the second opening; forming the auxiliary electrode on the insulating layer except the second opening, the auxiliary electrode electrically coupled to the second electrode through the at least one first opening; and removing the mask.

The first electrode may be a transparent electrode, and the second electrode may be a reflective electrode.

The second electrode and the auxiliary electrode may include a same conductive material.

According to another embodiment of the present invention, a method of manufacturing an organic light emitting display includes: forming at least one thin film transistor on a substrate; forming a first electrode electrically coupled to the thin film transistor on the substrate; forming an organic emission layer on the first electrode; forming a second electrode on a front surface of the substrate including the organic emission layer; and forming an auxiliary electrode in areas except an area overlapped with the organic emission layer on the second electrode, the auxiliary electrode electrically coupled to the second electrode.

The forming of the auxiliary electrode may include disposing a mask in the area overlapped with the organic emission layer on the second electrode; forming the auxiliary electrode on other area except the organic emission layer blocked by the mask on the second electrode, the auxiliary electrode electrically coupled to the second electrode; and removing the mask.

The first electrode may be a transparent electrode, and the second electrode may be a reflective electrode.

The second electrode and the auxiliary electrode may include a same conductive material.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a sectional view schematically showing an organic light emitting display according to an embodiment of the present invention.

FIGS. 2 to 8 are sectional views sequentially showing a process of manufacturing the organic light emitting display of FIG. 1.

FIG. 9 is a sectional view showing a state in which a particle attached to an organic light emitting diode is insulated in the organic light emitting display of FIG. 1.

FIGS. 10 to 15 are sectional views sequentially showing a process of repairing (or preparing) the organic light emitting display of FIG. 9.

FIG. 16 is a sectional view schematically showing an organic light emitting display according to another embodiment of the present invention.

FIG. 17 is a sectional view schematically showing an organic light emitting display according to still another embodiment of the present invention.

### DETAILED DESCRIPTION

In the following detailed description, only certain example embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” an other element, it can be directly on the other element, or be indirectly on the other element with one or more intervening elements interposed therebetween. Also, when an element is referred to as being “connected to” an other element, it can be directly connected to the other element or be indirectly connected to the other element with one or more intervening elements interposed therebetween. Hereinafter, like reference numerals refer to like elements. In the drawings, the thickness or size of layers are exaggerated for clarity and not necessarily drawn to scale.

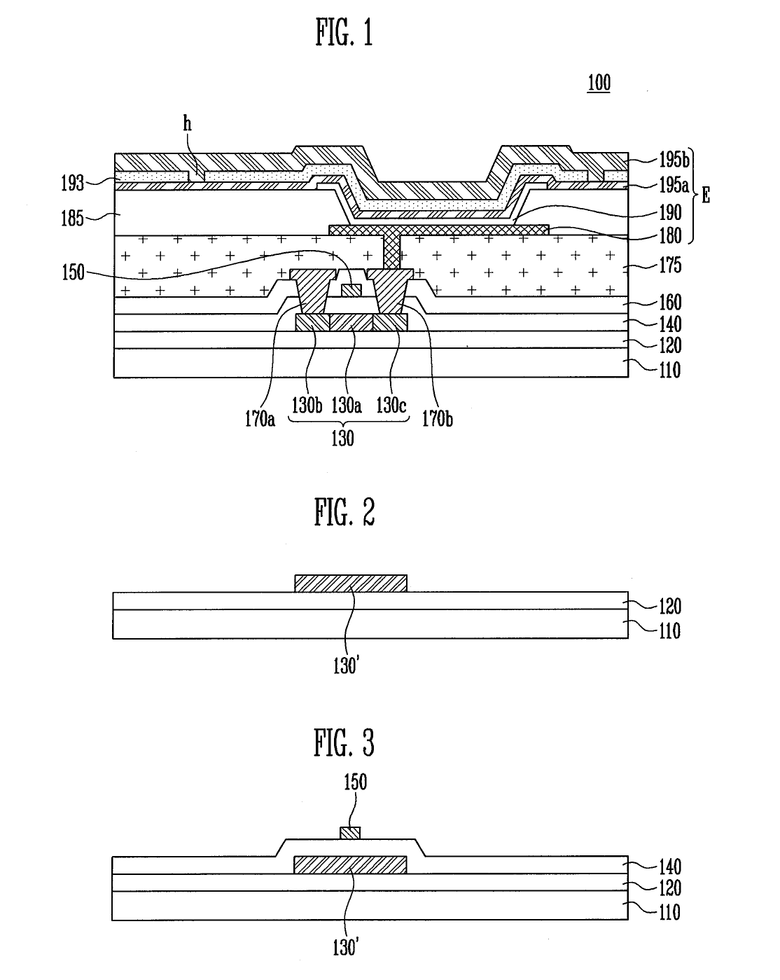

FIG. 1 is a sectional view schematically showing an organic light emitting display according to an embodiment of the present invention.

Referring to FIG. 1, the organic light emitting display 100 according to this embodiment includes a substrate 110, a buffer layer 120 formed on the substrate 110, a semiconductor layer 130 formed on the buffer layer 120, the semiconductor layer 130 including a source area 130b/an active area 130a/a drain area 130c, a first insulating layer 140 formed on the semiconductor layer 130, a gate electrode 150 formed on the first insulating layer 140, a second insulating layer 160 formed on the gate electrode 150, source and drain electrodes 170a and 170b formed on the second insulating layer 160, and a third insulating layer 175 formed on the source and drain electrodes 170a and 170b.

The organic light emitting display 100 according to this embodiment further includes a first electrode 180 formed on the third insulating layer 175, a pixel defining layer 185 provided with an opening through which one area of the first electrode 180 is exposed, an organic emission layer 190 formed on the pixel defining layer 185, a second electrode 195a formed on the pixel defining layer 185 including the organic emission layer 190, a fourth insulating layer 193 formed on the second electrode 195a, and an auxiliary electrode 195b formed on the fourth insulating layer 193 to be electrically coupled (e.g., electrically connected) to the second electrode 195a.

The first electrode 180, the organic emission layer 190, the second electrode 195a, and the auxiliary electrode 195b constitute an organic light emitting diode E.

The substrate 110 may be appropriately selected from a transparent substrate such as glass, a quartz substrate, a ceramic substrate, a silicon substrate, a flexible substrate such as plastic, or the like, according to the requirement of those skilled in the art. However, in one embodiment, in case of a bottom emission organic light emitting display, the substrate is formed of a transparent material.

The buffer layer 120 is formed on a front surface (a surface facing the organic light emitting display) of the substrate 110. The buffer layer 120 performs a function of protecting the semiconductor layer 130 (formed in a subsequent process) from the penetration of particles such as alkali ions, which is discharged from the substrate 110, and planarizing the surface of the substrate 110. The buffer layer 120 is not necessarily essential, and may be omitted according to the kind and process conditions of the substrate 110.

The semiconductor layer 130 is formed on the buffer layer 120, and includes the active area 130a into which an impurity is not injected, and the source and drain areas 130b and 130c formed by injecting a p-type (p-channel) or n-type (n-channel) impurity into both sides of the active area 130a. The impurity may be changed depending on a kind of a thin film transistor.

The first insulating layer 140 formed on the semiconductor layer 130 includes openings to allow portions of the respective source and drain areas 130b and 130c to be exposed therethrough. The first insulating layer 140, for example, includes an inorganic insulating material having a single layer structure with one of the layers selected from silicon oxide (SiO₂), silicon nitride (SiN), and silicon oxynitride (SiON); or a stacked layer structure with two or more of the layers selected from silicon oxide (SiO₂), silicon nitride (SiN), and silicon oxynitride (SiON).

The gate electrode 150 is formed at a portion overlapped with the active area 130a of the semiconductor layer 130 on the first insulating layer 140.

The second insulating layer 160 is formed of any suitable inorganic and/or organic insulating materials on the gate electrode 150, and includes the openings through which the portions of the respective source and drain areas 130b and 130c are exposed.

The source and drain electrodes 170a and 170b are formed on the second insulating layer 160. The source and drain electrodes 170a and 170b are respectively coupled to the source and drain areas 130b and 130c through the openings formed in the first and second insulating layers 140 and 160.

The third insulating layer 175 is formed of any suitable inorganic and/or organic insulating materials on the source and drain electrodes 170a and 170b, and includes an opening through which a portion of the drain electrode 170b is exposed to an outside thereof.

The first electrode 180 is formed of a transparent conductive material. The first electrode 180 is electrically coupled to the drain electrode 170b through the opening of the third insulating layer 175. The pixel defining layer 185 is formed on the first electrode 180, and includes an opening through which a portion of the first electrode 180 is exposed to an outside thereof. The organic emission layer 190 is formed on the first electrode 180 through the opening of the pixel defining layer 185.

The second electrode 195a acts as a reflective electrode on the pixel defining layer 185, and is formed of a low-resistance conductive material. The second electrode 195a has a thin thickness of about 70 to 200 Å, and is formed on the pixel defining layer 185 through vacuum evaporation in order to reduce or minimize damage of the organic emission layer 190.

The fourth insulating layer 193 is formed on a front surface of the second electrode 195a, and includes an opening h through which a portion of the second electrode 195a is exposed. The fourth insulating layer 193 may include any suitable inorganic and/or organic insulating materials. In one embodiment, the opening h of the fourth insulating layer 193 is formed in a non-emission area (e.g., formed in an area except, or outside where the organic emission layer 190 is located).

The fourth insulating layer 193 has a thickness of about 1 to 2 μm, and may be formed on the front surface (facing away from the substrate 110) of the second electrode 195a through any one method selected from vacuum evaporation and low damage physical vapor deposition (LDPVD) in order to reduce or minimize damage of the second electrode 195a.

The auxiliary electrode 195b is formed on the fourth insulating layer 193. The auxiliary electrode 195b is electrically coupled to the second electrode 195a positioned therebelow through the opening h of the fourth insulating layer 193. The second electrode 195a and the auxiliary electrode 195b are electrically coupled through the opening h of the fourth insulating layer 193 in the non-emission area.

The auxiliary electrode 195b has a thickness of 1500 to 3000 Å, and may be formed of a conductive material different from the second electrode 195a. However, in one embodiment, the auxiliary electrode 195b may be formed of the same conductive material as the second electrode 195a.

The auxiliary electrode 195b is formed of a low-resistance material in order to reduce line resistance of the second electrode 195a having a thin thickness. For example, the auxiliary electrode 195b may include a conductive material such as molybdenum (Mo), aluminum (Al) or silver (Ag).

In this case, the first electrode 180 acts as an anode electrode made of a transparent conductive material, and the second electrode 195a acts as a first cathode electrode of the reflective electrode. The auxiliary electrode 195b acts as a second cathode electrode for reducing resistance of the first cathode electrode (the second electrode).

When the second electrode 195a is formed on the organic emission layer 190 through the vacuum evaporation in order to reduce or minimize the damage of the organic emission layer 190, the second electrode 195a has a thin thickness (70 to 200 A) depending on deposition technique and process conditions.

The second electrode 195a with the thin thickness causes the line resistance of a large-sized organic light emitting display to be increased, thereby deteriorating the image quality. In order to reduce or prevent such a problem, the auxiliary electrode 195b made of a thick low-resistance conductive material is formed on the second electrode 195a.

In the organic light emitting display 100 according to this embodiment, the auxiliary electrode 195b with the thick thickness is formed on the second electrode 195a, so that it is possible to reduce the line resistance of the second electrode 195a, thereby reducing or preventing the deterioration of the image quality.

Further, when particles are attached on the first electrode 180, the fourth insulating layer 193 formed between the second electrode 195a and the auxiliary electrode 195b insulates the particles from the first electrode 180 and the second electrode 195a (formed in a subsequent process), so that it is possible to reduce or prevent the occurrence of a short circuit between the first and second electrodes 180 and 195a and the occurrence of dark spot defects caused by the particles (to be explained later).

Hereinafter, a process of manufacturing the organic light emitting display according to this embodiment will be described in more detail.

FIGS. 2 to 8 are sectional views sequentially showing a process of manufacturing the organic light emitting display of FIG. 1.

First, referring to FIG. 2, a buffer layer 120 is formed on a substrate 110 made of glass, plastic, etc. through chemical vapor deposition, plasma enhanced chemical vapor deposition, or the like. The buffer layer 120 may be made of an insulating material including an oxide, such as silicon oxide (SiO₂), aluminum oxide (Al₂O₃), hafnium oxide (HfO₃) or yttrium oxide (Y₂O₃).

Subsequently, a semiconductor material layer 130′ is deposited on a front surface of the substrate 110 having (with) the buffer layer 120 formed thereon. Continuously (next), a photosensitive film pattern is formed by coating a photosensitive film (such as a photoresist) on the semiconductor material layer 130′, and light-exposing the coated photosensitive film. The semiconductor material layer 130′ is patterned to remain in only a specific area of the buffer layer 120, using (utilizing) the photosensitive film pattern as a mask.

Next, referring to FIG. 3, a first insulating layer 140 is formed on the substrate 110 having the semiconductor material layer 130′ formed thereon. The first insulating layer 140 may be formed with a single layer including an insulative oxide (such as silicon oxide (SiOx)), or be formed with multiple layers configured with (including) a lower layer (including an insulative material such as silicon oxide (SiOx)) and an upper layer (including an insulating material).

Continuously (next), a gate electrode 150 is formed by forming a conductive material layer made of a metal or the like, and patterning the conductive material layer to be overlapped with a middle portion of the semiconductor material layer 130′.

The gate electrode 150 may be formed into a single-layered structure with a single material or a mixture of materials selected from the group consisting of molybdenum (Mo), tungsten (W), aluminum neodymium (AlNd), titanium (Ti), aluminum (Al), silver (Ag) and alloy thereof; or be formed into a double- or multi-layered structure with Mo, Al and/or Ag (which is a low-resistance material in order to reduce wire resistance). That is, the gate electrode 150 may be formed by sequentially laminating conductive layers of a multi-layered structure in order to reduce the wire resistance. For example, the gate electrode 150 may have a multi-layered structure including Mo/Al/Mo, MoW/AlNd/MoW, Mo/Ag/Mo, Mo/Ag alloy/Mo or Ti/Al/Mo.

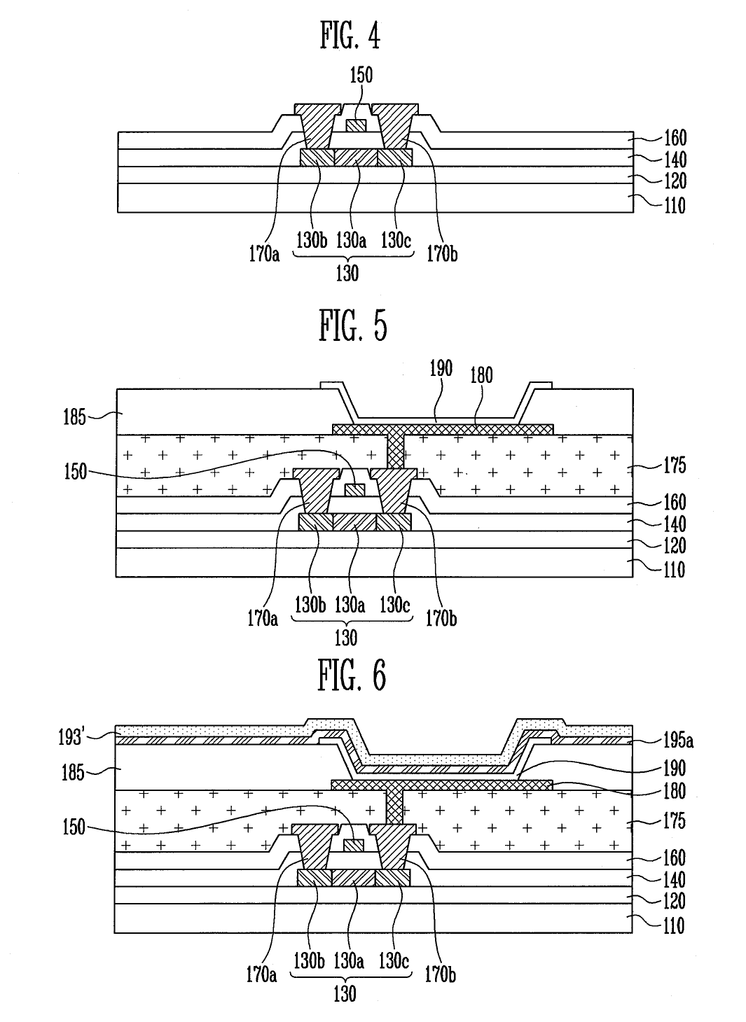

Next, referring to FIG. 4, a second insulating layer 160 is formed on the substrate 110 having the gate electrode 150 formed thereon. Subsequently, the first and second insulating layers 140 and 160 are patterned so that portions of the semiconductor material layer 130′ corresponding to the source and drain areas 130b and 130c are exposed.

Subsequently, a semiconductor layer 130 is formed by injecting a p-type (p-channel) or n-type (n-channel) impurity into the semiconductor material layer exposed to an outside, using (utilizing) the sequentially formed first and second insulating layers 140 and 160 as masks.

Through such a process, an active area 130a (overlapped with the gate electrode 150 so that an impurity are not injected thereinto), and the source and drain areas 130b and 130c (respectively formed at both sides of the active area 130a) are formed, with the source and drain areas 130b and 130c having an impurity injected thereinto.

Continuously (next), source and drain electrodes 170a and 170b are formed to be respectively coupled to the exposed source and drain areas 130b and 130c.

The source and drain electrodes 170a and 170b may be formed into a single-layered structure with a single material or a mixture of materials selected from the group consisting of Mo, W, AlNd, Ti, Al, Ag and alloy thereof; or be formed into a double- or multi-layered structure with Mo, Al and/or Ag (which is a low-resistance material in order to reduce wire resistance).

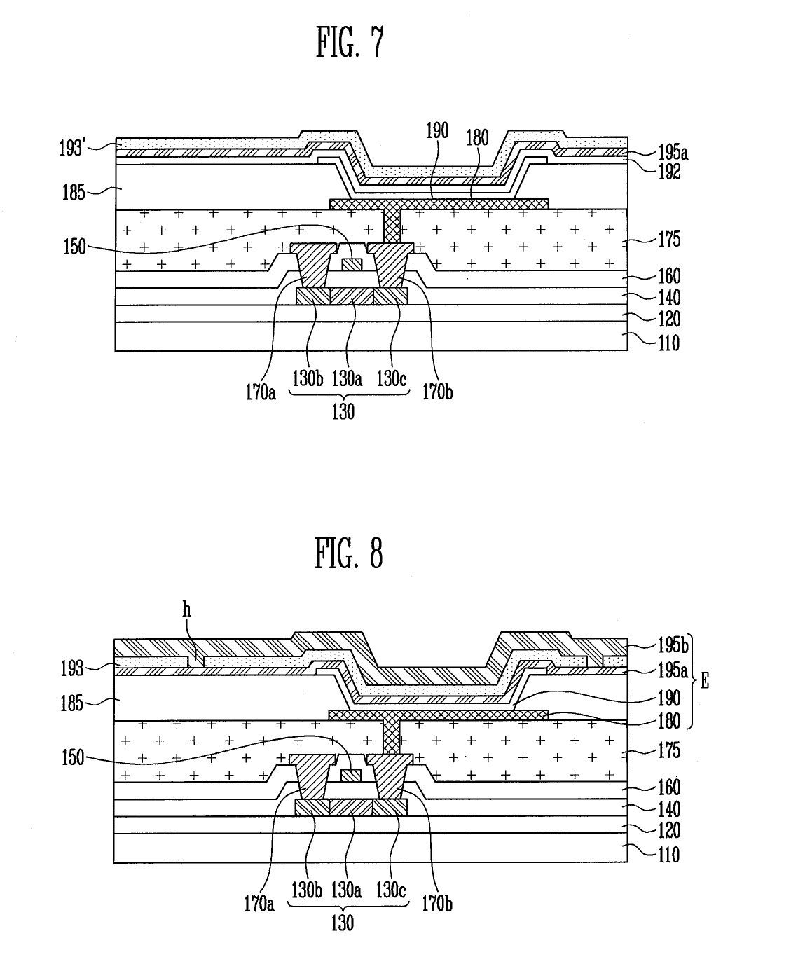

Next, referring to FIG. 5, a third insulating layer 175 is formed on the substrate 110 having the source and drain electrodes 170a and 170b formed thereon. In this case, the third insulating layer 175 is patterned to include a contact hole through which a portion of the drain electrode 170b is exposed to an outside thereof.

Continuously (next), a first electrode 180 electrically coupled to the drain electrode 170b through the contact hole is formed on the third insulating layer 175. The first electrode 180 may act as an anode electrode made of a transparent conductive material (such as ITO, IZO, ZnO or In₂O₃), which has a high work function.

Subsequently, a pixel defining layer 185 is formed on the third insulating layer 175 having the first electrode 180 formed thereon. The pixel defining layer 185 includes an opening (through which a portion of the first electrode 180 is exposed to an outside) formed through a photo process. The pixel defining layer 185 may be formed of an organic material selected from the group consisting of polyacryl series resin (polyacrylate based resin), epoxy resin, phenol resin, polyphenylene ether series resin (polyphenylene ether based resin), polyphenylene sulfide series resin (polyphenylene sulfide based resin), benzocyclobutene, and the like.

Subsequently, an organic emission layer 190 is formed on the first electrode 180 exposed to the outside through the opening. A low or high molecular weight organic layer may be used (utilized) as the organic emission layer 190. When the low molecular organic layer is used (utilized), the organic emission layer 190 may be formed by stacking into a single- or multi-layered structure, including one or more of a hole injection layer (HIL), a hole transport layer (HTL), an emission layer (EML), an electron transport layer (ETL), an electron injection layer (EIL), and the like.

Next, referring to FIG. 6, a second electrode 195a is formed on a front surface of the pixel defining layer 185 including the organic emission layer 190. Continuously (next), an insulating material layer 193′ is formed on a front surface of the second electrode 195a.

The second electrode 195a is deposited on the pixel defining layer 185 through vacuum evaporation in order to reduce or minimize damage of the organic emission layer 190. The second electrode 195a has a thickness of about 70 to 200 Å. The second electrode 195a is a reflective electrode and acts as a first cathode electrode of an organic light emitting diode E. The second electrode 195a may be formed of Ag, Mg, Al, Pt, Pd, Au, Ni, Nd, Ir, Cr, Li, Ca or the like, which has a low work function.

The insulating material layer 193′ has a thickness of about 1 to 2 μm, and may be formed of any one suitable inorganic and/or organic insulating materials.

The inorganic insulating material, for example, may include an insulative oxide such as silicon oxide (SiOₓ), silicon oxide (SiNₓ), tungsten oxide (WOₓ), aluminum oxide (AlₓOₓ), molybdenum oxide (MoOₓ), titanium oxide (TiOₓ), zinc oxide (ZnOₓ) or tin oxide (SnOₓ).

The organic insulating layer, for example, may include a general-purpose polymer (PMMA, PS), polymer derivatives including a phenol group, an acryl based polymer, an imide based polymer, an allyl ether based polymer, an amide based polymer, a fluorine based polymer, a vinyl alcohol based polymer, and/or the like.

In this case, the insulating material layer 193′ is deposited on a front surface of the second electrode 195a through any one method selected from vacuum deposition and low damage physical vapor deposition (LDPVD).

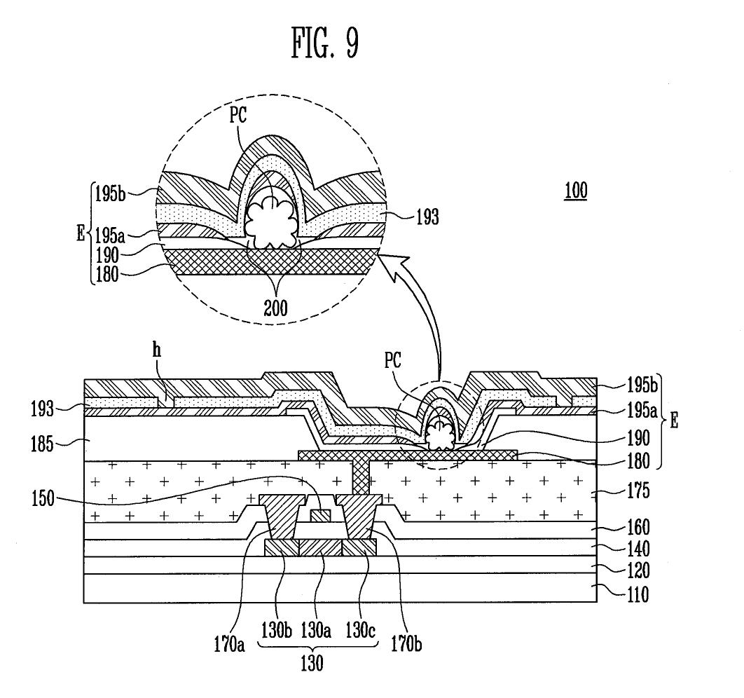

When a dummy layer 192 (such as tungsten oxide (WOₓ)) is formed between the organic emission layer 190 and the second electrode 195a in order to reduce or minimize the damage of the organic emission layer 190 as shown in FIG. 7, the insulating material layer 193′ may be deposited on the second electrode 195a through plasma enhanced chemical vapor deposition.

Next, referring to FIG. 8, a fourth insulating layer 193 is formed by patterning the insulating material layer (193′ of FIG. 6) to include an opening h through which a portion of the second electrode 195a is exposed to an outside. In this case, the opening h is formed in a non-emission area except (i.e., but not on) the organic emission layer 190 on the substrate 110.

Continuously (next), an auxiliary electrode 195b electrically coupled to the second electrode 195a through the opening h is formed on the fourth insulating layer 193. That is, the second electrode 195a and the auxiliary electrode 195b are electrically coupled through the opening h in the non-emission area.

The auxiliary electrode 195b is formed of a low-resistance conductive material (such as Mo, Al or Ag) for reducing line resistance of the second electrode 195a (having a thin thickness) depending on process conditions. The auxiliary electrode 195b has a thickness of about 1500 to 3000 Å. In one embodiment, the second electrode 195a and the auxiliary electrode 195b are formed of the same conductive material.

As described above, in the organic light emitting display 100 according to this embodiment, the auxiliary electrode 195b with a thick thickness (which is made of the low-resistance conductive material) is formed on the second electrode 195a so that it is possible to reduce the line resistance of the second electrode 195a, thereby reducing or preventing the deterioration of the image quality.

Further, in the organic light emitting display 100 according to this embodiment, the fourth insulating layer 193 is formed between the second electrode 195a and the auxiliary electrode 195b, so that when particles are attached on the first electrode 180, the fourth insulating layer 193 formed between the second electrode 195a and the auxiliary electrode 195b insulates the particles from the first electrode 180 and the second electrode 195a (formed in a subsequent process). Accordingly, it is possible to reduce or prevent the occurrence of a short circuit between the first and second electrodes 180 and 195a, and the occurrence of dark spot defects caused by the particles.

FIG. 9 is a sectional view showing a state in which a particle attached to an organic light emitting diode is insulated in the organic light emitting display of FIG. 1. In FIG. 9, components identical (or similar) to those of the aforementioned embodiment are designated by like reference numerals, and their detailed descriptions will not be repeated. Different portions from those of the aforementioned embodiment will be mainly described.

Referring to FIG. 9, the organic light emitting display 100 according to this embodiment includes a substrate 110, a buffer layer 120 formed on the substrate 110, a semiconductor layer 130 formed on the buffer layer 120, a first insulating layer 140 formed on the semiconductor layer 130, a gate electrode 150 formed on the first insulating layer 140, a second insulating layer 160 formed on the gate electrode 150, source and drain electrodes 170a and 170b formed on the second insulating layer 160, a third insulating layer 175 formed on the source and drain electrodes 170a and 170b, a first electrode 180 formed on the third insulating layer 175, a pixel defining layer 185 formed on the first electrode 180, an organic emission layer 190 formed on the pixel defining layer 185, a second electrode 195a formed on the organic emission layer 190, a fourth insulating layer 193 formed on the second electrode 195a, and an auxiliary electrode 195b formed on the fourth insulating layer 193 to be electrically coupled to the second electrode 195a.

The first electrode 180, the organic emission layer 190, the second electrode 195a, and the auxiliary electrode 195b constitute an organic light emitting diode E.

When the organic light emitting diode E is formed, a particle (hereinafter, referred to as a “PC”) generated in a process may be attached on a surface of the first electrode 180. If the PC is attached on the surface of the first electrode 180, the second electrode 195a (to be formed in a subsequent process) is short-circuited with the first electrode 180, and therefore, a dark spot defect may be caused (formed).

The organic emission layer 190 is formed on the first electrode 180 having the PC attached thereon through vacuum evaporation or the like. Particles constituting the organic emission layer 190 are interrupted by the PC attached on the surface of the first electrode 180, and therefore are not deposited at a boundary portion between the surface of the first electrode 180 and the PC. Accordingly, an empty space 200 is formed in a lower area of the PC.

The second electrode 195a is formed on the organic emission layer 190 through the vacuum evaporation in order to reduce or minimize damage of the organic emission layer 190. The deposition time of the second electrode 195a is reduced as short as possible so that when forming on the organic emission layer 190, the second electrode 195a is not filled in the empty space 200 formed in the lower area of the PC.

As the deposition time of the second electrode 195a becomes shorter, the thickness of the second electrode 195a formed on the organic emission layer 190 may become thinner. In one embodiment, the second electrode 195a has a thickness of about 7 to 200 Å.

The fourth insulating layer 193 is formed on the second electrode 195a through any one method selected from vacuum evaporation and low damage physical vapor deposition. In this case, the fourth insulating layer 193 is formed on the empty space 200 formed in the lower area of the PC and the second electrode 195a.

The fourth insulating layer 193 has a thickness of about 1 to 2 μm, and includes an opening h through which a portion of the second electrode 195a is exposed to an outside in other areas except the organic emission layer 190.

The auxiliary electrode 195b is formed on the fourth insulating layer 193. The auxiliary electrode 195b is electrically coupled to the second electrode 195a in a non-emission area through the opening h. In this case, the auxiliary electrode 195b is formed of a low-resistance conductive material having a thickness of about 1500 to 3000 Å in order to reduce line resistance of the second electrode 195a.

Since the fourth insulating layer 193 is formed on the empty space 200 formed in the lower area of the PC and the second electrode 195a, the PC is insulated from a portion (of the second electrode 195a) to which the PC is not attached, so that it is possible to reduce or minimize dark spot defects that may occur at shorted portions of the first and second electrodes 180 and 195a, thereby improving image quality.

Hereinafter, a method for repairing (or preparing) the organic light emitting display according to this embodiment will be described in more detail.

FIGS. 10 to 15 are sectional views sequentially showing a process of repairing the organic light emitting display of FIG. 9.

First, referring to FIG. 10, a buffer layer 120 is formed on a substrate 110. Subsequently, a semiconductor material layer 130′ is formed on a front surface of the substrate 110 having the buffer layer 120 formed thereon, and then patterned to remain in only a specific area of the buffer layer 120.

Next, referring to FIG. 11, a first insulating layer 140 is formed on the substrate 110 having the semiconductor material layer 130′ formed thereon. Continuously (next), a gate electrode 150 is formed by forming a conductive material layer made of a metal or the like on the first insulating layer 140 and patterning the conductive material layer to be overlapped with a middle portion of the semiconductor material layer 130′.

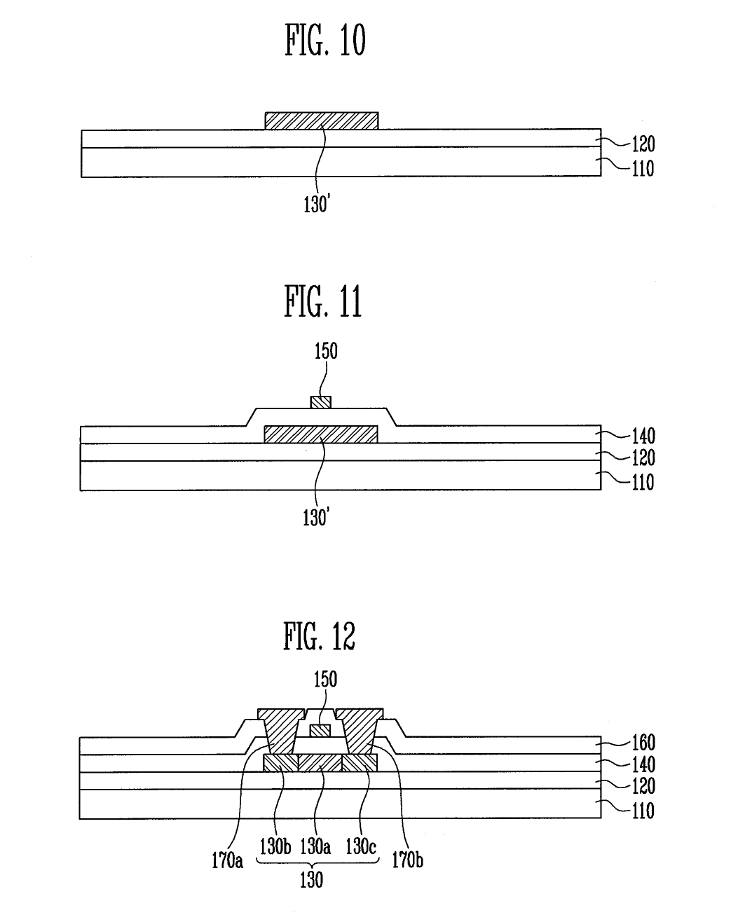

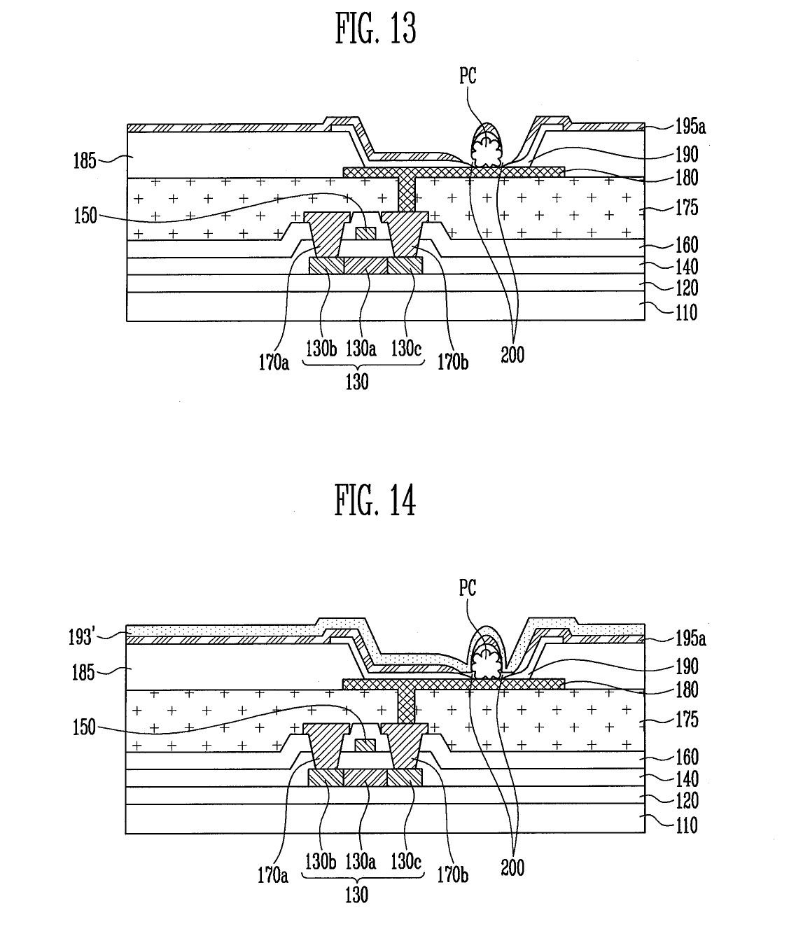

Next, referring to FIG. 12, a second insulating layer 160 is formed on the substrate 110 having the gate electrode 150 formed thereon. Subsequently, the first and second insulating layers 140 and 160 are patterned so that portions of source and drain areas 130b and 130c are exposed.

Subsequently, a semiconductor layer 130 is formed by injecting a p-type (p-channel) or n-type (n-channel) impurity into the semiconductor material layer exposed to an outside, using (utilizing) the sequentially formed first and second insulating layers 140 and 160 as masks.

Through such a process, an active area 130a is formed to be overlapped with the gate electrode 150 so that an impurity are not injected thereinto, and the source and drain areas 130b and 130c are respectively formed at both sides of the active area 130a, with the source and drain areas 130b and 130c having an impurity injected thereinto.

Continuously (next), source and drain electrodes 170a and 170b are formed to be respectively coupled to the exposed source and drain areas 130b and 130c.

Next, referring to FIG. 13, a third insulating layer 175 is formed on the source and drain electrodes 170a and 170b. In this case, the third insulating layer 175 is patterned to include a contact hole through which a portion of the drain electrode 170b is exposed to an outside.

Continuously (next), a first electrode 180 electrically coupled to the drain electrode 170b through the contact hole is formed on the third insulating layer 175.

The first electrode 180 is formed on the third insulating layer 175 through a deposition process. In this case, a PC such as an impurity is generated while the first electrode 180 is being formed in a deposition chamber, and therefore, may be attached on a surface of the first electrode 180.

A pixel defining layer 185 is formed on the first electrode 180 having the PC attached thereon. The pixel defining layer 185 includes an opening through which a portion of the first electrode 180 is exposed to an outside through a photo process.

Continuously (next), an organic emission layer 190 is formed on the first electrode 180 exposed to the outside through the opening. Particles (materials) constituting the organic emission layer 190 are not deposited at a boundary portion between the surface of the first electrode 180 and the PC due to the PC attached on the surface of the first electrode 180.

Subsequently, a second electrode 195a is formed on the organic emission layer 190 through vacuum evaporation so that an empty space 200 formed in a lower area of the PC is not filled with the second electrode 195a.

Next, referring to FIG. 14, an insulating material layer 193′ is formed on a front surface of the second electrode 195a. The insulating material layer 193′ has a thickness of about 1 to 2 μm, and may be formed of any suitable inorganic and/or organic insulating materials. In this case, the insulating material layer 193′ is formed on the second electrode 195a.

Next, referring to FIG. 15, a fourth insulating layer 193 is formed by patterning the insulating material layer (193′ of FIG. 14) to include an opening h through which the a portion of the second electrode 195a is exposed to an outside. Continuously (next), an auxiliary electrode 195b electrically coupled to the second electrode 195a through the opening h is formed on the fourth insulating layer 193.

The fourth insulating layer 193 is formed on the second electrode 195a with the empty space 200 to insulate the PC from the first and second electrodes 180 and 195a, and thus it is possible to reduce or minimize the occurrence of a dark spot defect caused due to the PC, thereby improving image quality.

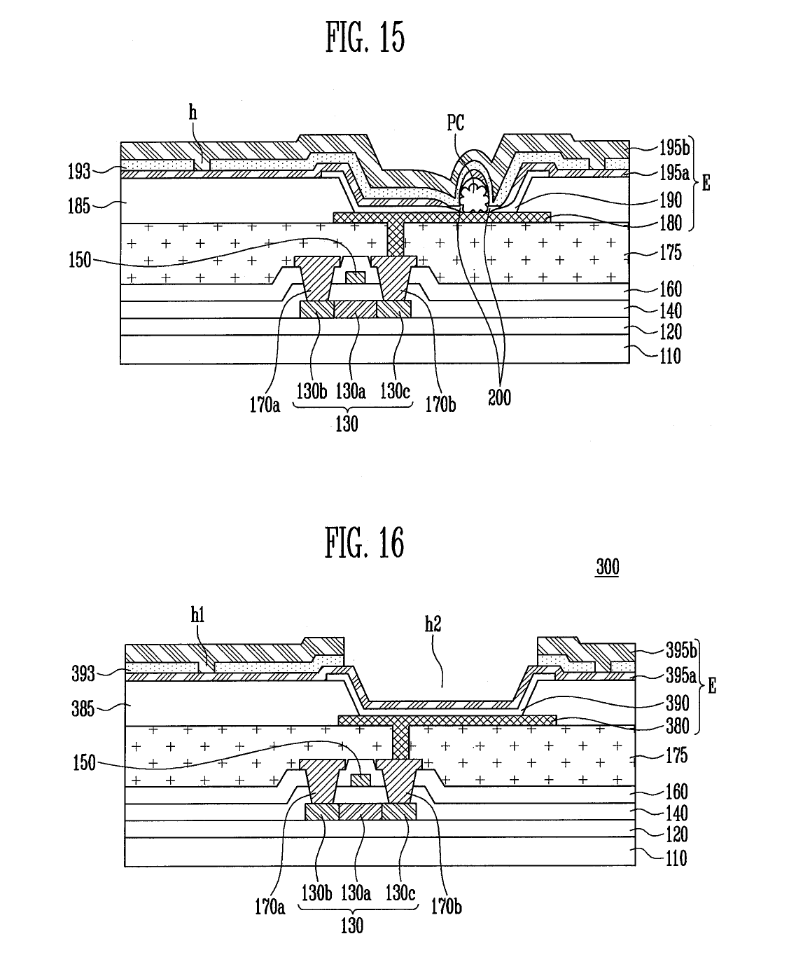

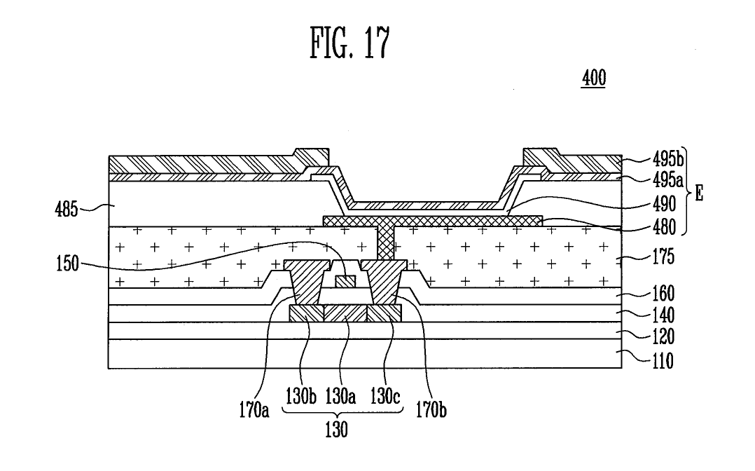

FIG. 16 is a sectional view schematically showing an organic light emitting display according to another embodiment of the present invention.

Referring to FIG. 16, the organic light emitting display 300 includes a substrate 110, a buffer layer 120 formed on the substrate 110, a semiconductor layer 130 formed on the buffer layer 120, the semiconductor layer 130 including a source area 130b/an active area 130a/a drain area 130c, a first insulating layer 140 formed on the semiconductor layer 130, a gate electrode 150 formed on the first insulating layer 140, a second insulating layer 160 formed on the gate electrode 150, source and drain electrodes 170a and 170b formed on the second insulating layer 160, and a third insulating layer 175 formed on the source and drain electrodes 170a and 170b.

The organic light emitting display 300 according to this embodiment further includes a first electrode 380 formed on the third insulating layer 175, a pixel defining layer 385 provided with an opening through which one area of the first electrode 380 is exposed, an organic emission layer 390 formed on the pixel defining layer 385, a second electrode 395a formed on the pixel defining layer 385 including the organic emission layer 390, a fourth insulating layer 393 formed on the second electrode 395a, and an auxiliary electrode 395b formed on the fourth insulating layer 393 to be electrically coupled to the second electrode 395a.

The first electrode 380, the organic emission layer 390, the second electrode 395a, and the auxiliary electrode 395b constitute an organic light emitting diode E.

The first electrode 380 is formed of a transparent conductive material. The first electrode 380 is formed on the third insulating layer 175 to be electrically coupled to the drain electrode 170b through an opening. The pixel defining layer 385 is formed on the first electrode 380 and patterned so that a portion of the first electrode 380 is exposed to an outside. The organic emission layer 390 is formed on the first electrode 380 exposed to the outside.

The second electrode 395a acts as a reflective electrode on the pixel defining layer 385, and is formed of a low-resistance conductive material. The second electrode 395a has a thin thickness of about 70 to 200 Å, and is formed on the pixel defining layer 385 through vacuum evaporation in order to reduce or minimize damage of the organic emission layer 390.

The fourth insulating layer 393 includes a first opening h1 through which a portion of the second electrode 395a is exposed to an outside in a non-emission area, and a second opening h2 through which a portion of the second electrode 395a is exposed to the outside in an area corresponding to the organic emission layer 390.

The fourth insulating layer 393 may include any suitable inorganic and/or organic insulating materials. The fourth insulating layer 393 has a thickness of about 1 to 2 μm, and may be formed on the second electrode 395a through any one method selected from vacuum evaporation and low damage physical vapor deposition.

The auxiliary electrode 395b is formed on the fourth insulating layer 393 to be overlapped with the fourth insulating layer 393. Thus, the auxiliary electrode 395b is electrically coupled to the second electrode 395a in the non-emission area through the first opening h1. The auxiliary electrode 395b has a thickness of about 1500 to 3000 Å, and may be formed of a conductive material different from the second electrode 395a. However, in one embodiment, the auxiliary electrode 395b may be formed of the same conductive material as the second electrode 395a.

The auxiliary electrode 395b is formed of a low-resistance material in order to reduce line resistance of the second electrode 395a with the thin thickness. For example, the auxiliary electrode 395b may include a conductive material such as Mo, Al or Ag.

The first electrode 380 acts as an anode electrode made of a transparent conductive material, and the second electrode 395a acts as a first cathode electrode of the reflective electrode. The auxiliary electrode 395b acts as a second cathode electrode for reducing resistance of the first cathode electrode (the second electrode).

When the auxiliary electrode 395b is formed on the fourth insulating layer 393, a mask used (utilized) to form the organic emission layer 390 is disposed above the second opening h2 of the fourth insulating layer 393, so that the auxiliary electrode 395b can be formed on only the fourth insulating layer 393.

The mask is disposed above the second opening h2 in order to reduce or prevent a particle that may be generated in the formation of the auxiliary electrode 395b from being attached to an upper portion of the second electrode 395a exposed to the outside through the second opening h2.

FIG. 17 is a sectional view schematically showing an organic light emitting display according to still another embodiment of the present invention.

Referring to FIG. 17, the organic light emitting display 400 according to this embodiment includes a substrate 110, a buffer layer 120 formed on the substrate 110, a semiconductor layer 130 formed on the buffer layer 120, the semiconductor layer 130 including a source area 130b/an active area 130a/a drain area 130c, a first insulating layer 140 formed on the semiconductor layer 130, a gate electrode 150 formed on the first insulating layer 140, a second insulating layer 160 formed on the gate electrode 150, source and drain electrodes 170a and 170b formed on the second insulating layer 160, and a third insulating layer 175 formed on the source and drain electrodes 170a and 170b.

The organic light emitting display 400 further includes a first electrode 480 formed on the third insulating layer 175, a pixel defining layer 485 provided with an opening through which one area of the first electrode 480 is exposed, an organic emission layer 490 formed on the pixel defining layer 485, a second electrode 495a formed on the pixel defining layer 485 including the organic emission layer 490, and an auxiliary electrode 495b formed on the second electrode 495a to be electrically coupled to the second electrode 495a.

The first electrode 480, the organic emission layer 490, the second electrode 495a, and the auxiliary electrode 495b constitute an organic light emitting diode E.

The first electrode 480 is formed of a transparent conductive material. The first electrode 480 is formed on the third insulating layer 175 to be electrically coupled to the drain electrode 170b through an opening. The pixel defining layer 485 includes an opening through which a portion of the first electrode 480 is exposed. The organic emission layer 490 is formed on the first electrode 480 through the opening of the pixel defining layer 485.

The second electrode 495a acts as a reflective electrode on the pixel defining layer 485, and is formed of a low-resistance conductive material. The second electrode 495a has a thin thickness of about 70 to 200 Å, and is formed on the pixel defining layer 485 through any one method selected from vacuum evaporation and low damage physical vapor deposition (LDPVD) in order to reduce or minimize damage of the organic emission layer 490.

The auxiliary electrode 495b has a thickness of about 1500 to 3000 Å, and may be formed of a conductive material different from the second electrode 495a. However, in one embodiment, the auxiliary electrode 495b may be formed of the same conductive material as the second electrode 495a. The auxiliary electrode 495b is only formed in other areas except an area corresponding to the organic emission layer 490 on the second electrode 495a (i.e., the auxiliary electrode 495b is not formed in the area corresponding to the organic emission layer 490 on the second electrode 495a).

The auxiliary electrode 495b is formed of a low-resistance material in order to reduce line resistance of the second electrode 495a with the thin thickness. For example, the auxiliary electrode 495b may include a conductive material such as Mo, Al or Ag.

The first electrode 480 acts as an anode electrode made of a transparent conductive material, and the second electrode 495a acts as a first cathode electrode of the reflective electrode. The auxiliary electrode 495b acts as a second cathode electrode for reducing resistance of the first cathode electrode (the second electrode).

When the auxiliary electrode 495b is formed on the second electrode 495a, a mask used (utilized) to form the organic emission layer 490 is disposed above an area corresponding to the organic emission layer 490, so that the auxiliary electrode 495b can be formed in only other areas except the organic emission layer 490 on the second electrode 495a.

The mask is disposed above the area corresponding to the organic emission layer 490 on the second electrode 495a in order to reduce or prevent a particle that may be generated in the formation of the auxiliary electrode 495b from being attached to an upper portion of the second electrode 495a. Accordingly, it is possible to reduce or prevent the occurrence of dark spot defects that may occur in an emission area.

By way of summation and review, as the size of an organic light emitting display gradually increases, the resistance of a cathode electrode increases, and therefore, a problem such as an IR drop is caused (created). In order to reduce or prevent such a problem, there was proposed a method for reducing the resistance of the cathode electrode by forming an auxiliary cathode electrode having a thick thickness on the cathode electrode.

When the thickness of the auxiliary electrode increases to implement low resistance of the cathode electrode, there is a limitation in forming an oxide layer on a surface of the cathode electrode in a repair process. Therefore, a particle attached on the anode electrode cannot be insulated. Further, a display defect occurs at a portion where an anode electrode and the cathode electrode are short-circuited with each other, and therefore, the deterioration of image quality is caused (created).

As described above, according to the present invention, the insulating layer is formed on the cathode electrode with the thin thickness, and the auxiliary electrode electrically coupled to the cathode electrode is formed in the non-emission area of the insulating layer, so that it is possible to effectively insulate particles attached to the organic light emitting diode. Accordingly, it is possible to reduce or minimize the occurrence of dark spot defects and to improve image quality.

Example embodiments have been disclosed herein, and although specific terms are employed, they are used (utilized) and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used (utilized) singularly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims, and equivalents thereof.

What is claimed is:

1. An organic light emitting display, comprising:
a substrate with at least one thin film transistor thereon;
a first electrode electrically coupled to the thin film transistor on the substrate;
an organic emission layer on the first electrode;
a second electrode on the organic emission layer;
an insulating layer on the second electrode; and
an auxiliary electrode on the insulating layer and electrically coupled to the second electrode.

2. The organic light emitting display of claim 1, wherein the first electrode is a transparent electrode and the second electrode is a reflective electrode.

3. The organic light emitting display of claim 1, wherein the second electrode and the auxiliary electrode include a same conductive material.

4. The organic light emitting display of claim 1, wherein the insulating layer has at least one opening through which a portion of the second electrode is exposed to an outside, the opening being only in other areas except an area in which the organic emission layer is formed.

5. The organic light emitting display of claim 1, wherein the insulating layer and the auxiliary electrode are on a front surface of the substrate.

6. The organic light emitting display of claim 1, wherein the insulating layer and the auxiliary electrode are only in other areas except an area in which the organic emission layer is formed on the substrate.

7. The organic light emitting display of claim 1, wherein a thickness of the second electrode is 70 to 200 Å, and a thickness of the auxiliary electrode is 1500 to 3000 Å.

8. An organic light emitting display, comprising:
a substrate with at least one thin film transistor thereon;
a first electrode electrically coupled to the thin film transistor on the substrate;
an organic emission layer on the first electrode;
a second electrode on the organic emission layer; and
an auxiliary electrode on the second electrode and electrically coupled to the second electrode.

9. The organic light emitting display of claim 8, wherein the first electrode is a transparent electrode, and the second electrode is a reflective electrode.

10. The organic light emitting display of claim 8, wherein the second electrode and the auxiliary electrode include a same conductive material.

11. The organic light emitting display of claim 8, wherein the auxiliary electrode is only in other areas except an area in which the organic emission layer is formed on the substrate.

12. A method of manufacturing an organic light emitting display, the method comprising:
forming at least one thin film transistor on a substrate;
forming a first electrode electrically coupled to the thin film transistor on the substrate;
forming an organic emission layer on the first electrode;
forming a second electrode on the organic emission layer;
forming an insulating layer on the second electrode, the insulating layer patterned to include at least one opening through which a portion of the second electrode is exposed to an outside; and
forming an auxiliary electrode electrically coupled to the second electrode through the opening on the insulating layer.

13. The method of claim 12, wherein the forming of the insulating layer and the forming of the auxiliary electrode comprise:
forming an insulating material layer on a front surface of the substrate with the second electrode formed thereon;
forming the insulating layer including the at least one opening through which a portion of the second electrode is exposed to the outside by patterning a portion of the insulating material layer not overlapped with the organic emission layer; and
forming an auxiliary electrode on a front surface of the insulating layer to be electrically coupled to the second electrode through the at least one opening.

14. The method of claim 12, wherein the forming of the insulating layer and the forming of the auxiliary electrode comprises:
forming an insulating material layer on a front surface of the substrate with the second electrode formed thereon;
forming the insulating layer with at least one opening through which a portion of the second electrode is exposed to the outside by patterning a portion of the insulating material layer not overlapped with the organic emission layer, and further forming a second opening through which a portion of the second electrode is exposed to the outside by patterning a portion of the insulating material layer overlapped with the organic emission layer;
disposing a mask on the second opening;
forming the auxiliary electrode on the insulating layer except the second opening, the auxiliary electrode electrically coupled to the second electrode through the at least one first opening; and
removing the mask.

15. The method of claim 12, wherein the first electrode is a transparent electrode, and the second electrode is a reflective electrode.

16. The method of claim 12, wherein the second electrode and the auxiliary electrode include a same conductive material.

17. A method of manufacturing an organic light emitting display, the method comprising:
forming at least one thin film transistor on a substrate;
forming a first electrode electrically coupled to the thin film transistor on the substrate;
forming an organic emission layer on the first electrode;
forming a second electrode on a front surface of the substrate including the organic emission layer; and
forming an auxiliary electrode only in other areas except an area overlapped with the organic emission layer on the second electrode, the auxiliary electrode electrically coupled to the second electrode.

18. The method of claim 17, wherein the forming of the auxiliary electrode comprises:
disposing a mask in the area overlapped with the organic emission layer on the second electrode;
forming the auxiliary electrode on other area except the organic emission layer blocked by the mask on the second electrode, the auxiliary electrode being electrically coupled to the second electrode; and
removing the mask.

19. The method of claim 17, wherein the first electrode is a transparent electrode, and the second electrode is a reflective electrode.

20. The method of claim 17, wherein the second electrode and the auxiliary electrode include a same conductive material.
